(19) United States
(12) Patent Application Publication
(10) Pub. No.: US 2026/0229616 A1
(43) Pub. Date: Aug. 6, 2026

(54) METHOD FOR MANUFACTURING SECONDARY BATTERY

(71) Applicant: Prime Planet Energy & Solutions, Inc., Tokyo (JP)

(72) Inventors: Yuya YANO, Kasai-shi, Hyogo-ken (JP); Shigeto TAMEZANE, Kakogawa-shi, Hyogo-ken (JP); Yuma KAMIYAMA, Osaka-shi Osaka-fu (JP)

(21) Appl. No.: 19/529,114

(22) Filed: Feb. 4, 2026

(30) Foreign Application Priority Data
Feb. 5, 2025 (JP) 2025-017928

(51) Int. Cl. H01M 10/42; H01M 10/052; H01M 10/0525; H01M 10/0585; H01M 10/0587; H01M 10/44; H01M 10/48; H01M 50/103; H01M 50/105; H01M 50/178; H01M 50/204; H01M 50/417; H01M 50/46

(52) U.S. Cl. CPC H01M 10/4235; H01M 10/052; H01M 10/0525; H01M 10/0585; H01M 10/0587; H01M 10/42; H01M 10/425; H01M 10/44; H01M 10/441; H01M 10/443; H01M 10/48; H01M 10/482; H01M 10/486; H01M 10/488; H01M 50/103; H01M 50/105; H01M 50/178; H01M 50/204; H01M 50/417; H01M 50/46

(57) ABSTRACT

A method for manufacturing a secondary battery disclosed herein includes: measuring a first voltage V₁ that is an inter-terminal voltage before an aging process, for each battery assembly; performing the aging process for each battery assembly; measuring a second voltage V₂ that is an inter-terminal voltage after the aging process, for each battery assembly; calculating a voltage difference ΔV between the first voltage V₁ and the second voltage V₂ for each battery assembly; plotting the first voltage V₁ and the voltage difference ΔV in each battery assembly on coordinates having the first voltage V₁ as a first axis and the voltage difference ΔV as a second axis, thereby acquiring a regression curve indicating a distribution tendency of the battery assemblies on the coordinates; and performing pass/fail determination for each battery assembly based on the regression curve. This can precisely inspect the presence or absence of an internal short circuit.

### CROSS REFERENCE TO RELATED APPLICATIONS

This application claims the benefit of priority to Japanese Patent Application No. 2025-017928 filed on Feb. 5, 2025. The entire contents of this application are hereby incorporated herein by reference.

### BACKGROUND

### 1. Technical Field

The technology disclosed herein relates to a method for manufacturing a secondary battery.

### 2. Description of the Related Art

One example of defects that may occur during the manufacture of a secondary battery includes an internal short circuit caused by contamination with foreign matter or the like. In order to detect defective products having such an internal short circuit, in a manufacturing process of a secondary battery, an inter-terminal voltage is measured before and after an aging process in which the battery after initial charging is left to stand for a long period of time. In a defective product having an internal short circuit, since a positive electrode and a negative electrode are electrically connected, the inter-terminal voltage gradually decreases after the initial charging. Therefore, a battery having a large voltage difference ΔV between before and after the aging process can be determined to be a defective product having an internal short circuit. One example of a method for manufacturing a secondary battery, including such an inspection process, is disclosed in Japanese Patent Application Publication No. 2006-253027.

### SUMMARY

In recent years, there has been a demand for the development of a technology capable of inspecting the presence or absence of occurrence of an internal short circuit with higher precision than in the conventional art. The technology disclosed herein has been made in response to such a demand.

A method for manufacturing a secondary battery disclosed herein includes the steps of: measuring a first voltage V₁ for each of the plurality of battery assemblies, the first voltage V₁ being an inter-terminal voltage before an aging process; performing the aging process for each of the plurality of battery assemblies; measuring a second voltage V₂ for each of the plurality of battery assemblies, the second voltage V₁ being an inter-terminal voltage after the aging process; calculating a voltage difference ΔV between the first voltage V₁ and the second voltage V₂ for each of the plurality of battery assemblies; plotting the first voltage V₁ and the voltage difference ΔV in each of the plurality of battery assemblies on coordinates having the first voltage V₁ as a first axis and the voltage difference ΔV as a second axis, thereby acquiring a regression curve indicating a distribution tendency of the plurality of battery assemblies on the coordinates; and performing pass/fail determination for each of the plurality of battery assemblies based on the regression curve.

As will be described in detail later, the present inventors have found a tendency that, as a time from completion of initial charging to start of measurement of the first voltage V₁ (hereinafter also referred to as a “measurement start time”) becomes longer, the voltage difference ΔV between before and after the aging process becomes smaller. In an actual manufacturing site for secondary batteries, a very large number of battery assemblies are fabricated, and therefore it is difficult to align the measurement start times for all of the battery assemblies. As a result, for a battery assembly having a later measurement start time, the voltage difference ΔV before and after the aging process tends to become smaller, and thus there is a possibility that such a battery assembly may be determined to be a non-defective product despite the occurrence of an internal short circuit. On the other hand, for a battery assembly having an earlier measurement start time, the voltage difference ΔV tends to become larger, and thus there is a possibility that such a battery assembly may be determined to be a defective product even when no internal short circuit has occurred. In contrast, in the manufacturing method disclosed herein, a regression curve reflecting variations in the voltage difference ΔV due to differences in the measurement start time is acquired, and pass/fail determination is performed based on the regression curve. Accordingly, the presence or absence of occurrence of an internal short circuit can be determined without being affected by the measurement start time. As a result, according to the manufacturing method disclosed herein, the presence or absence of occurrence of an internal short circuit can be inspected with higher precision than in the conventional art.

### BRIEF DESCRIPTION OF THE DRAWINGS

FIG. 1 is a flowchart of a method for manufacturing a secondary battery according to a first embodiment.

FIG. 2 is a cross-sectional view schematically illustrating an internal structure of a battery assembly.

FIG. 3 is a schematic exploded perspective view of an electrode assembly in the battery assembly illustrated in FIG. 2.

FIG. 4 is an example of a graph for explaining acquisition of a regression straight line R₁ represented by a linear equation.

FIG. 5 is a flowchart of a pass/fail determination step in the first embodiment.

FIG. 6 is a graph obtained by correcting the graph illustrated in FIG. 4 using the regression straight line R₁.

FIG. 7 is a flowchart of a pass/fail determination step in a second embodiment.

FIG. 8 is a graph illustrating another example of pass/fail determination based on the regression straight line R₁.

FIG. 9 is an example of a graph for explaining acquisition of a regression curve R₂ represented by a quadratic equation.

FIG. 10 is a graph obtained by correcting the graph illustrated in FIG. 9 using the regression curve R₂.

FIG. 11 is an example of a graph for explaining acquisition of a regression curve R₃ represented by a cubic equation.

FIG. 12 is a graph obtained by correcting the graph illustrated in FIG. 11 using the regression curve R₃.

FIG. 13 is a flowchart of a method for manufacturing a secondary battery according to a fourth embodiment.

FIG. 14 is a flowchart of a pass/fail determination step in a fifth embodiment.

### DETAILED DESCRIPTION

Hereinafter, embodiments of a method for manufacturing a second battery disclosed herein will be described with reference to the drawings. The following embodiments are not intended to limit the technology disclosed herein. In addition, each of the drawings is schematically illustrated and does not necessarily reflect actual objects. Further, members and portions having the same functions are denoted by the same reference numerals as appropriate, and a duplicate description thereof is omitted as appropriate.

### First Embodiment

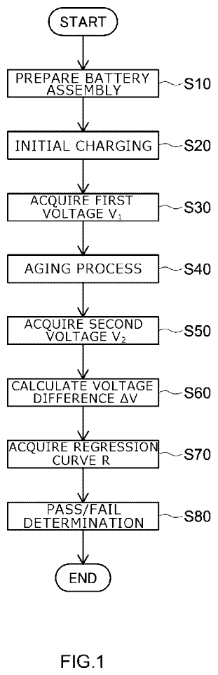

First, a first embodiment of the manufacturing method disclosed herein will be described. FIG. 1 is a flowchart of the method for manufacturing a secondary battery according to the first embodiment. As illustrated in FIG. 1, the manufacturing method according to the present embodiment includes a preparation step S10, an initial charging step S20, a first voltage measurement step S30, an aging step S40, a second voltage measurement step S50, a voltage difference calculation step S60, a regression curve acquisition step S70, and a pass/fail determination step S80. Each step will be described below.

### 1. Preparation Step S10

In the preparation step S10, a plurality of battery assemblies is prepared. Here, the term “preparation” is a concept that broadly encompasses not only fabrication of battery assemblies but also purchase, reuse, and the like. As will be described in detail later, in the manufacturing method according to the present embodiment, a regression curve R and a threshold value are set based on measurement results of a first voltage V₁ and a voltage difference ΔV of each of the plurality of battery assemblies. Thus, in the manufacturing method according to the present embodiment, it is preferable to prepare a predetermined number or more of battery assemblies as inspection targets. This enables inspection with high accuracy. For example, the number of battery assemblies prepared in the present step is preferably 5 or more, more preferably 10 or more, further preferably 20 or more, and particularly preferably 100 or more. On the other hand, when such a large number of battery assemblies are prepared, it becomes difficult to align measurement start times for the respective battery assemblies. As a result, variation in the voltage difference ΔV due to a difference in the measurement start time, which will be described later (hereinafter also simply referred to as “variation in the voltage difference ΔV”), tends to increase. However, according to the manufacturing method disclosed herein, even when such a variation in the voltage difference ΔV occurs, any battery assemblies having an internal short circuit can be detected precisely. That is, the manufacturing method disclosed herein is suitable for use, especially when a large number of battery assemblies are prepared. On the other hand, the upper limit of the number of battery assemblies is not particularly limited and may be 10,000 or less, 1,000 or less, 100 or less, or 10 or less.

Hereinafter, an example of a structure of the battery assembly will be described. The term “battery assembly” in the present specification refers to a structure in which constituent elements of a secondary battery are assembled to a state in which charging and discharging are possible, and which has not yet been subjected to inspection for an internal short circuit after the aging process. Further, the term “secondary battery” in the present specification refers to a battery assembly in which no internal short circuit occurs and which is determined to be ready for shipment. In the following description, the manufacturing of a lithium-ion secondary battery will be described; however, this is not intended to limit a manufacturing target of the manufacturing method disclosed herein. That is, the manufacturing method disclosed herein can also be used for manufacturing secondary batteries other than lithium-ion secondary batteries (such as nickel-metal hydride batteries).

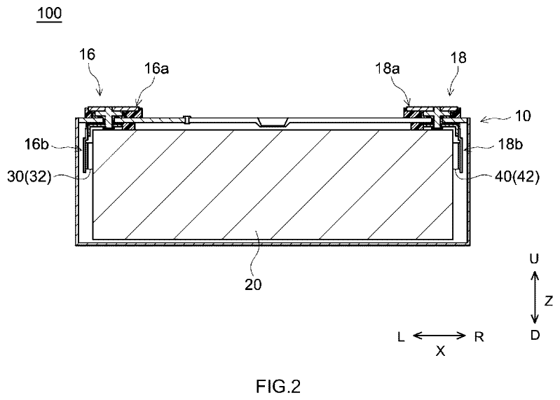

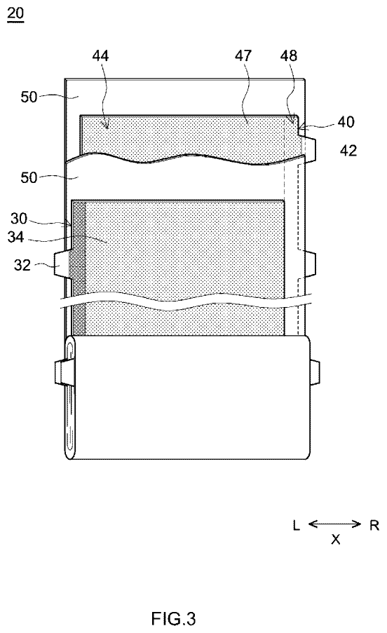

FIG. 2 is a cross-sectional view schematically illustrating an internal structure of the battery assembly. FIG. 3 is a schematic exploded perspective view of an electrode assembly in the battery assembly illustrated in FIG. 2. In FIGS. 2 and 3, reference signs X and Y indicate a width direction and a height direction, respectively. Further, reference signs R, L, U, and D in FIGS. 2 and 3 indicate right, left, up, and down, respectively. However, these directions are defined for convenience of explanation and are not intended to limit an installation orientation of a battery during manufacturing or use.

The battery assembly 100 illustrated in FIG. 2 includes a case 10, an electrode assembly 20, and an electrolyte (not illustrated). Each component will be described below. Materials of these components are not particularly limited, and any conventionally known materials can be used therefor without restriction; therefore, a detailed description thereof is omitted.

As illustrated in FIG. 2, the case 10 is a rectangular housing. The electrode assembly 20 and the electrolyte are accommodated inside the case 10. In addition, a positive electrode terminal 16 and a negative electrode terminal 18 are attached to the case 10. An upper end 16a of the positive electrode terminal 16 is exposed to the outside of the case 10. Meanwhile, a lower end 16b of the positive electrode terminal 16 is connected to a positive electrode 30 of the electrode assembly 20 within the case 10. Further, an upper end 18a of the negative electrode terminal 18 is also exposed to the outside of the case 10. A lower end 18b of the negative electrode terminal 18 is connected to a negative electrode 40 of the electrode assembly 20 within the case 10.

As illustrated in FIG. 3, the electrode assembly 20 includes the positive electrode 30, the negative electrode 40, and a separator 50. Specifically, the electrode assembly 20 illustrated in FIG. 3 is a wound electrode assembly in which a laminated body composed of the positive electrode 30, the negative electrode 40, and the separator 50 is wound. However, the structure of the electrode assembly is not particularly limited, and any other conventionally known structures (such as a laminated electrode assembly) may also be employed.

The positive electrode 30 includes a positive electrode core body 32, which is a conductive foil body, and a positive electrode active material layer 34 provided on a surface of the positive electrode core body 32. In addition, positive electrode tabs 36 protrude from portions of a left-side edge L of the positive electrode 30. Each positive electrode tab 36 is a portion in which the positive electrode active material layer 34 is not provided and from which the positive electrode core body 32 is exposed. The positive electrode tabs 36 are connected to the lower end 16b of the positive electrode terminal 16 (see FIG. 2). Meanwhile, the negative electrode 40 includes a negative electrode core body 42, which is a conductive foil body, and a negative electrode active material layer 44 provided on a surface of the negative electrode core body 42. In addition, negative electrode tabs 46 protrude from portions of a right-side edge R of the negative electrode 40. Each negative electrode tab 46 is a portion in which the negative electrode active material layer 44 is not provided and from which the negative electrode core body 42 is exposed. The negative electrode tabs 46 are connected to the lower end 18b of the negative electrode terminal 18 (see FIG. 2). The separator 50 is an insulating sheet interposed between the positive electrode 30 and the negative electrode 40. The separator 50 has a plurality of fine pores formed therein, each pore having a submicron size. Through the pores of the separator 50, charge carriers (such as Li ions) move between the positive electrode 30 and the negative electrode 40.

Here, in the electrode assembly 20 with the above-described configuration, when a large amount of Li ions move from the positive electrode 30 to the negative electrode 40, metallic Li may be deposited on a surface of the negative electrode 40. In contrast, the electrode assembly 20 illustrated in FIG. 3 is configured such that a width w2 of the negative electrode active material layer 44 is larger than a width w1 of the positive electrode active material layer 34. In other words, in the present embodiment, the negative electrode 40 includes an opposed region 47 that is opposed to the positive electrode 30 and a non-opposed region 48 that is not opposed to the positive electrode 30. As a result, a capacity of the negative electrode 40 can become larger than a capacity of the positive electrode 30, thereby suppressing deposition of metallic Li during charging.

### 2. Initial Charging Step S20

As illustrated in FIG. 1, in the manufacturing method according to the present embodiment, the initial charging step S20 is performed after the preparation step S10. In the initial charging step S20, initial charging is performed on each of the plurality of battery assemblies 100. Note that conditions for the initial charging are not particularly limited, and any conventionally known conditions can be employed without restriction. However, in the present step, the initial charging is preferably performed such that a state of charge (SOC) of each battery assembly 100 falls within a range of 0% to 60%. This facilitates detection of a minute short circuit because of a large magnitude of a voltage decrease.

### 3. First Voltage Measurement Step S30

Next, in the first voltage measurement step S30, a first voltage V₁, which is an inter-terminal voltage before the aging process, is measured for each of the plurality of battery assemblies 100. Note that the term “inter-terminal voltage” in the present specification refers to a voltage that can be measured using conventionally known measurement techniques, and does not limit the technology disclosed herein. Thus, a detailed measurement procedure of the inter-terminal voltage is omitted.

A time from an end of the initial charging step S20 to a start of the first voltage measurement step S30 (the time being also referred to as a measurement start time) is preferably 720 hours or less, more preferably 336 hours or less, and particularly preferably 168 hours or less. Reducing the measurement start time can contribute to an improvement in productivity of secondary batteries. Meanwhile, reducing the measurement start time tends to cause variations in the first voltage V₁ and the voltage difference ΔV among the plurality of battery assemblies 100 (details thereof will be described later). However, according to the manufacturing method of the present embodiment, even when variations in the first voltage V₁ and the voltage difference ΔV occur, defective products having an internal short circuit can be accurately detected. The measurement start time is preferably 12 hours or more, more preferably 24 hours or more, and particularly preferably 48 hours or more. Consequently, variations in the first voltage V₁ and the voltage difference ΔV are easily suppressed, thereby enabling detection of defective products with higher precision.

### 4. Aging Step S40

In the aging step S40, an aging process is performed for each of the plurality of battery assemblies 100. Specifically, in the present step, the battery assemblies 100 are retained in a constant-temperature chamber where a predetermined temperature is maintained. Aging conditions at this time are preferably adjusted as appropriate according to a type or structure of the battery assembly 100. The temperature of the aging process may be set within a range of, for example, 20° C. to 75° C. (preferably, 40° C. to 65° C.). Further, a duration of the aging process may be set within a range of 1 day to 15 days (preferably, 2 days to 7 days).

### 5. Second Voltage Measurement Step S50

In the second voltage measurement step S50, a second voltage V₂, which is an inter-terminal voltage after the aging process, is measured for each of the plurality of battery assemblies 100. The second voltage V₂ can be measured using the same procedure as that used for the first voltage V₁ described above. The present step is preferably performed after the battery assemblies 100 heated by the aging process are sufficiently cooled. As a result, fluctuations in measurement results due to measurement temperature can be suppressed. Specifically, the second voltage V₂ is preferably measured after the battery assemblies 100 have been cooled to a temperature of 10° C. to 40° C. (preferably, 15° C. to 30° C.).

### 6. Voltage Difference Calculation Step S60

In the voltage difference calculation step S60, a voltage difference ΔV between the first voltage V₁ and the second voltage V₂ is calculated for each of the plurality of battery assemblies 100. Here, in a normal battery assembly 100, the second voltage V₂ after the aging process slightly decreases from the first voltage V₁ due to diffusion of Li ions into the non-opposed region 48 during the aging process. On the other hand, in a battery assembly 100 in which an internal short circuit has occurred, the positive electrode 30 and the negative electrode 40 are electrically connected, thus decreasing the second voltage V₂ significantly from the first voltage V₁. Thus, the presence or absence of occurrence of an internal short circuit can be determined by confirming an amount of decrease in the inter-terminal voltage during the aging process (i.e., the voltage difference ΔV between the first voltage V₁ and the second voltage V₂).

### 7. Regression Curve Acquisition Step S70

In the regression curve acquisition step S70, the first voltage V₁ and the voltage difference ΔV in each of the plurality of battery assemblies 100 are plotted on coordinates having the first voltage V₁ as a first axis (horizontal axis) and the voltage difference ΔV as a second axis (vertical axis), whereby a regression curve R indicating a distribution tendency of the plurality of battery assemblies 100 on the coordinates is acquired. As a result, the presence or absence of occurrence of an internal short circuit can be determined without being affected by the measurement start time. Hereinafter, a case where a regression straight line R₁ represented by a linear equation (Y=aX+b) is acquired will be described in detail as an example of the regression curve R.

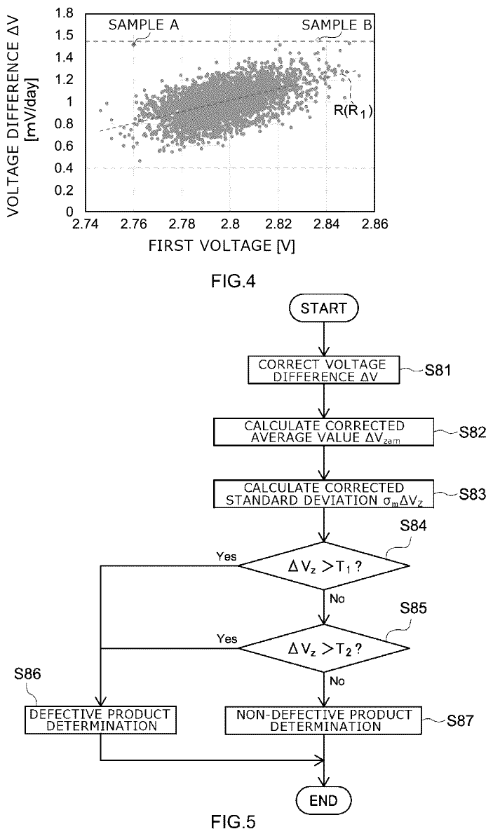

FIG. 4 is an example of a graph for explaining acquisition of the regression straight line R₁ represented by a linear equation. In FIG. 4, a first voltage V₁ and a voltage difference ΔV of each of 3,164 battery assemblies 100 are plotted. When inter-terminal voltages of such a large number of battery assemblies 100 are measured in this way, fluctuations occur in the first voltage V₁ before the aging process, even if the initial charging conditions and measurement conditions are aligned among the battery assemblies 100. Fluctuations in the first voltage V₁ are caused by the measurement start time, which is a duration from the end of the initial charging step S20 to the start of the first voltage measurement step S30. Specifically, when the first voltage V₁ is measured for a large number of battery assemblies 100, there occurs a certain time difference in the measurement start time (for example, about 2 hours) between a battery assembly 100 measured first and a battery assembly 100 measured last. At this time, in a battery assembly 100 measured at an early stage, diffusion of Li ions into the non-opposed region 48 of the negative electrode 40 does not sufficiently progress, resulting in a high first voltage V₁. Further, in the battery assembly 100 measured at the early stage, diffusion of Li ions into the non-opposed region 48 progresses during the aging step S40, making it more likely that the second voltage V₂ significantly decreases from the first voltage V₁ (that is, the voltage difference ΔV tends to be larger). Thus, the battery assembly 100 measured at the early stage tends to be plotted in an upper-right region of the graph illustrated in FIG. 4. On the other hand, in a battery assembly 100 measured at a later stage, diffusion of Li ions into the non-opposed region 48 sufficiently progresses, and in this state, the first voltage V₁ is measured, resulting in a low first voltage V₁. Further, in the battery assembly 100 measured at the later stage, the amount of diffusion of Li ions during the aging step S40 is small, making it more likely that the voltage difference ΔV before and after the aging step S40 decreases. As a result, the battery assembly 100 measured at the later stage tends to be plotted in a lower-left region of the graph illustrated in FIG. 4.

As described above, when the voltage difference ΔV before and after the aging step S40 is measured for a large number of battery assemblies 100, variations in the voltage difference ΔV occur due to differences in the measurement start time. For example, in an example illustrated in FIG. 4, an upward-sloping variation in the voltage difference ΔV is observed such that as the first voltage V₁ becomes higher (that is, as the measurement start time becomes shorter), the voltage difference ΔV also becomes higher. At this time, Sample A in FIG. 4 exhibits a relationship between the first voltage V₁ and the voltage difference ΔV that significantly differs from those of the other battery assemblies 100, indicating a high likelihood of an internal short circuit. However, Sample A, which is measured at a later stage, may be determined to be a non-defective product because an absolute value of the voltage difference ΔV thereof is reduced. On the other hand, Sample B exhibits a relationship between the first voltage V₁ and the voltage difference ΔV that is substantially the same as that of other battery assemblies 100, indicating a high likelihood of a normal battery assembly. However, Sample B, which is measured at an early stage, may be determined to be a defective product because an absolute value of the voltage difference ΔV thereof is increased. As described above, variations in the voltage difference ΔV due to differences in the measurement start time can be a factor that reduces the inspection accuracy for an internal short circuit. In contrast, in the regression curve acquisition step S70 according to the present embodiment, a regression straight line R₁ indicating a distribution tendency of plots of the plurality of battery assemblies 100 is acquired. By performing the pass/fail determination step S80 described later based on the regression straight line R₁, the pass/fail determination excluding the variations in the voltage difference ΔV can be performed precisely.

### 8. Pass/Fail Determination Step S80

Next, in the pass/fail determination step S80 of the present embodiment, pass/fail determination is performed for each of the plurality of battery assemblies 100 based on the regression curve R. The pass/fail determination based on the regression curve R (regression straight line R₁) is not limited to a specific form and may employ various forms. Hereinafter, the pass/fail determination step S80 in the first embodiment will be described. FIG. 5 is a flowchart of the pass/fail determination step in the first embodiment. As illustrated in FIG. 5, the pass/fail determination step S80 in the first embodiment includes a voltage difference correction step S81, a corrected average value calculation step S82, a corrected standard deviation calculation step S83, a first determination step S84, and a second determination step S85.

### (1) Voltage Difference Correction Step S81

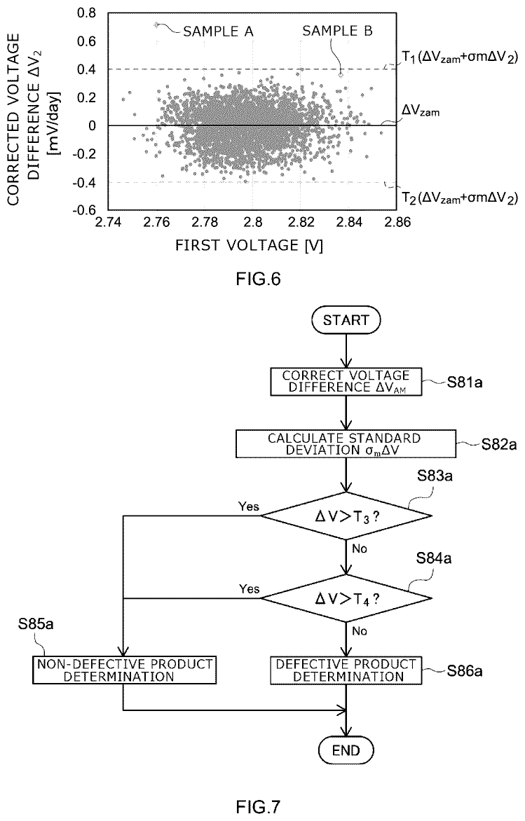

In the voltage difference correction step S81, when a slope of the regression straight line R₁ is denoted by (a) and an intercept thereof is denoted by (b), the voltage difference ΔV of each of the plurality of battery assemblies 100 is corrected to a corrected voltage difference ΔV_{z} based on the following equation (1). FIG. 6 is a graph obtained by correcting the graph illustrated in FIG. 4 using the regression straight line R₁. As described above, when the first voltage V₁ and the voltage difference ΔV of a large number of battery assemblies 100 are measured, an upward-sloping variation in the voltage difference ΔV is observed such that as the first voltage V₁ increases (that is, as the measurement start time becomes shorter), the voltage difference ΔV also becomes higher (see FIG. 4). In contrast, when the voltage difference ΔV of each plot is corrected using the regression straight line R₁, a graph in which such an upward-sloping variation is eliminated is obtained, as illustrated in FIG. 6.

$${ΔV}_{z} = ΔV - ( a \times {V}_{1} + b ) \qquad ( 1 )$$

### (2) Corrected Average Value Calculation Step S82

In the corrected average value calculation step S82, a corrected average value ΔV_{zam}, which is an average value of the corrected voltage differences ΔV_{z} of the plurality of battery assemblies 100, is calculated. Since the average value is calculated using a well-known calculation method, a detailed description thereof is omitted. FIG. 6 illustrates an aggregate of corrected voltage differences of the plurality of battery assemblies 100, obtained by setting the corrected average value ΔV_{zam} to the median value (0 mV/day).

### (3) Corrected Standard Deviation Calculation Step S83

In the corrected standard deviation calculation step S83, a corrected standard deviation σmΔV_{z}, which is a standard deviation of the corrected voltage differences ΔV_{z} of the plurality of battery assemblies 100, is calculated. The corrected standard deviation σmΔV_{z} is a standard deviation with respect to the corrected average value ΔV_{zam} obtained in the corrected average value calculation step S82. The standard deviation is calculated using a well-known calculation means, and a detailed description thereof is omitted.

### (4) First Determination Step S84

In the first determination step S84, a sum (ΔV_{zam}+σmΔV_{z}) of the corrected average value ΔV_{zam} and the corrected standard deviation σmΔV_{z} is set as a first threshold T₁. A battery assembly having a corrected voltage difference ΔV_{z} exceeding a first threshold T₁ is determined to be a defective product. That is, in the present step, a battery assembly 100 in which a voltage decrease deviating beyond a positive standard deviation (+σmΔV_{z}) is confirmed is determined to have an internal short circuit. For example, in FIG. 6, which is the corrected graph, the corrected voltage difference ΔV_{z} of Sample A significantly exceeds the first threshold T₁ (Yes in S84). In this case, as illustrated in the processing flow illustrated in FIG. 5, the processing proceeds to step S86, in which the battery assembly 100 to be inspected is determined to be a defective product. As described above, in the pass/fail determination step S80 of the present embodiment, the corrected voltage difference ΔV_{z} from which variations in the voltage difference ΔV due to differences in the measurement start time have been eliminated is used for the pass/fail determination. Accordingly, a battery assembly 100 (Sample A) that is difficult to exclude as a defective product by a conventional determination based on the voltage difference ΔV can be determined to be a defective product. On the other hand, in FIG. 6, which is the corrected graph, the corrected voltage difference ΔV_{z} of Sample B is equal to or less than the first threshold T₁ (No in S84). That is, according to the manufacturing method of the present embodiment, a possibility that a normal battery assembly 100 is excluded as a defective product due to a variation in the voltage difference ΔV can be reduced. In this case, the processing illustrated in the processing flow of FIG. 5 proceeds to the second determination step S85.

### (2) Second Determination Step S85

In the second determination step S85, a difference (ΔV_{zam}−σmΔV_{z}) between the corrected average value ΔV_{zam} and the corrected standard deviation σmΔV_{z} is set as a second threshold T₂. A battery assembly 100 having a corrected voltage difference ΔV_{z} less than the second threshold T₂ is determined to be a defective product. In the present step, a battery assembly 100 having an extremely small corrected voltage difference ΔV_{z} before and after the aging step S40 is determined to be a defective product. Such a battery assembly 100 has no internal short circuit; however, there is a possibility that a measurement error derived from measurement equipment has occurred. Thus, by setting the second threshold T₂ based on a negative standard deviation (−σmΔV_{z}), defects different from an internal short circuit can also be detected. When there exists a battery assembly 100 having a corrected voltage difference ΔV_{z} less than the second threshold T₂ (Yes in S85), the processing illustrated in the processing flow proceeds to step S86, in which the battery assembly 100 to be inspected is determined to be a defective product. On the other hand, the processing for a battery assembly 100 having a corrected voltage difference ΔV_{z} equal to or greater than the second threshold T₂ proceeds to step S87, and is determined to be a non-defective product. The battery assembly 100 that has been determined to be a non-defective product is conveyed to a subsequent step as a secondary battery ready for shipment.

The first embodiment of the manufacturing method disclosed herein has been described above. In the manufacturing method according to the first embodiment, the regression straight line R₁ is acquired to reflect variations in the voltage difference ΔV due to differences in the measurement start time. Then, using this regression straight line R₁, the voltage difference ΔV of each of the battery assemblies 100 is corrected. Thus, pass/fail determination can be performed based on the corrected voltage difference ΔV_{z} from which the above-described variation in the voltage difference ΔV has been eliminated. Therefore, according to the manufacturing method of the first embodiment, the presence or absence of occurrence of an internal short circuit can be inspected with higher precision than in the conventional art.

### Second Embodiment

The manufacturing method disclosed herein is not limited to the first embodiment described above, and may be modified in various ways. Hereinafter, a second embodiment of the manufacturing method disclosed herein will be described. Note that a difference between the first embodiment and the second embodiment is a procedure of the pass/fail determination step S80. That is, the procedure from the preparation step to the regression curve acquisition step in the second embodiment is substantially the same as those in the first embodiment, and detailed descriptions thereof are omitted.

FIG. 7 is a flowchart of the pass/fail determination step S80 in the second embodiment. As illustrated in FIG. 7, the pass/fail determination step S80 in the second embodiment includes an average value calculation step S81a, a standard deviation calculation step S82a, a third determination step S83a, and a fourth determination step S84a. Each step will be described below.

### (1) Average Value Calculation Step S81a

In the average value calculation step S81a, an average value ΔVₐₘ of the voltage differences ΔV of the plurality of battery assemblies 100 is calculated. That is, in the second embodiment, an average value of the voltage differences ΔV that have not been corrected using the regression curve R (regression straight line R₁) is calculated. This feature differs from the corrected average value calculation step S82 in the first embodiment (see FIG. 5).

### (2) Standard Deviation Calculation Step S82a

In the standard deviation calculation step S82a, a standard deviation σmΔV of the voltage differences ΔV of the plurality of battery assemblies 100 is calculated. The standard deviation σmΔV calculated in the present step is also a standard deviation of the voltage differences ΔV that have not been corrected using the regression curve R.

### (3) Third Determination Step S83a

In the present step, when a slope of the regression straight line R₁ is denoted by (a), and a value ΔV_{D1} represented by the following equation (2) is set as a third threshold T₃. A battery assembly having a voltage difference ΔV exceeding the third threshold T₃ is determined to be a defective product. That is, in the second embodiment, the regression straight line R₁ is used not for correction of the voltage difference ΔV but for setting of the threshold value. Specific details will be described below.

$${ΔV}_{D 1} = a \times {V}_{1} + ( {ΔV}_{am} + σ m ΔV ) \qquad ( 2 )$$

FIG. 8 is a graph illustrating another example of the pass/fail determination based on the regression straight line R₁. As illustrated in FIG. 8, in the manufacturing method according to the second embodiment, a straight line ΔV_{D1} parallel to the regression straight line R₁ is set as a third threshold T₃. Thus, the pass/fail determination can be performed in consideration of variations in the voltage difference ΔV due to the measurement start time. Specifically, in the present embodiment, an average value ΔVₐₘ and a standard deviation σmΔV of the voltage differences ΔV are calculated. Then, a straight line ΔV_{D1} having, as an intercept, a sum (ΔVₐₘ+σmΔV) of the average value ΔVₐₘ and the standard deviation σmΔV, and having the same slope (a) as the regression straight line R₁ is set on two-dimensional coordinates. In this case, Sample A exceeding the straight line ΔV_{D1} (third threshold T₃) is determined to be highly likely to have an internal short circuit because its voltage difference ΔV is significantly large in consideration of the measurement start time (first voltage V₁) (Yes in S83a in FIG. 7). On the other hand, Sample B falling below the straight line ΔV_{D1} (third threshold T₃) is determined to have no internal short circuit because its voltage difference ΔV falls within an allowable range in consideration of the measurement start time (first voltage V₁) (No in S83a in FIG. 7). In this case, the processing illustrated in the processing flow proceeds to the fourth determination step S84a.

### (4) Fourth Determination Step S84a

In the fourth determination step S84a, a value ΔV_{D2} represented by the following equation (3) is set as a fourth threshold T₄. A battery assembly 100 having a voltage difference ΔV less than the fourth threshold T₄ is determined to be a defective product. In the present step, a straight line ΔV_{D2} having, as an intercept, a difference (ΔVₐₘ−σmΔV) between the average value ΔVₐₘ and the standard deviation σmΔV and having the same slope (a) as the regression straight line R₁ is set as the fourth threshold T₄. Thus, it is possible to precisely determine whether a measurement error derived from measurement equipment has occurred in each of the plurality of battery assemblies 100, in consideration of the differences in the measurement start time.

$${ΔV}_{D 2} = a \times {V}_{1} + ( {ΔV}_{am} - σ m ΔV ) \qquad ( 3 )$$

As described above, in the second embodiment, the regression curve R (regression straight line R₁) is used not for correction of the voltage difference ΔV but for setting of the threshold value. Even in this case, the pass/fail determination can be performed in consideration of variations in the voltage difference ΔV due to differences in the measurement start time. That is, the second embodiment also enables detection of the presence or absence of occurrence of an internal short circuit with high precision.

### Third Embodiment

As described above, in the manufacturing methods according to the first and second embodiments, the straight line (regression straight line R₁) represented by the linear equation is acquired in the regression curve acquisition step S70 (see FIGS. 4 and 8). However, in the manufacturing method disclosed herein, a regression curve R represented by a quadratic or higher-order polynomial may also be used. Hereinafter, an embodiment using a regression curve R of a quadratic or higher-order equation will be described.

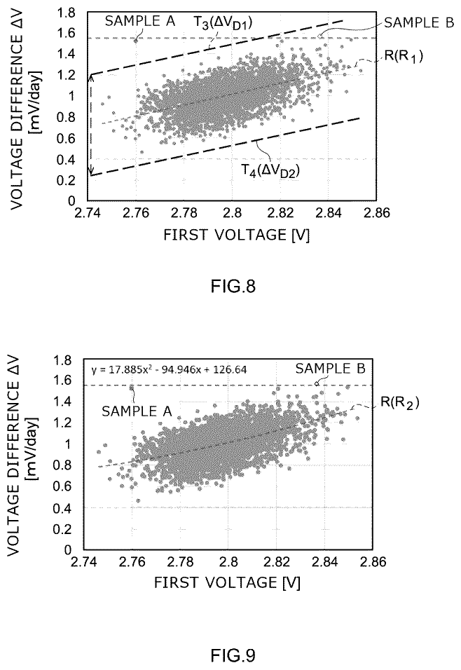

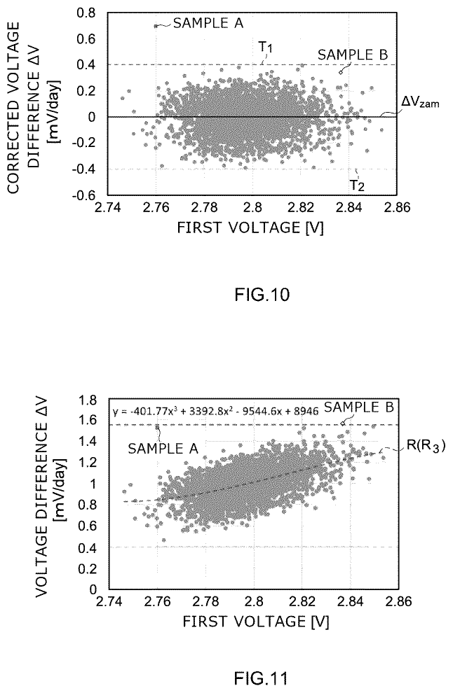

FIG. 9 is an example of a graph for explaining acquisition of a regression curve R₂ represented by a quadratic equation. As illustrated in FIG. 9, when variations in the voltage difference ΔV due to the measurement start time occur, a quadratic regression curve R₂ can also be acquired as the regression curve R indicating a tendency of such variations. The quadratic regression curve R₂ can be represented by the following equation (4). When the voltage difference ΔV is corrected using the regression curve R₂, it is preferable to use the following equation (5). Even when the correction is performed using this quadratic regression curve R₂, a corrected voltage difference ΔV_{z} from which variations due to the measurement start time have been eliminated can be obtained. FIG. 10 is a graph obtained by correcting the graph illustrated in FIG. 9, using the regression curve R₂. As illustrated in FIG. 10, even when the correction using the quadratic regression curve R₂ is performed, the determination based on the first threshold T₁ can be carried out in the same procedure as in the first embodiment.

$$Y = {aX}^{2} + bX + c \qquad ( 4 )$$

$${ΔV}_{z} = Y - ( {aX}^{2} + bX + c ) \qquad ( 5 )$$

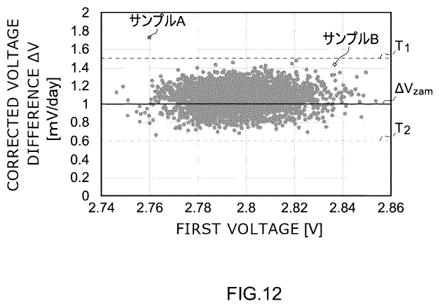

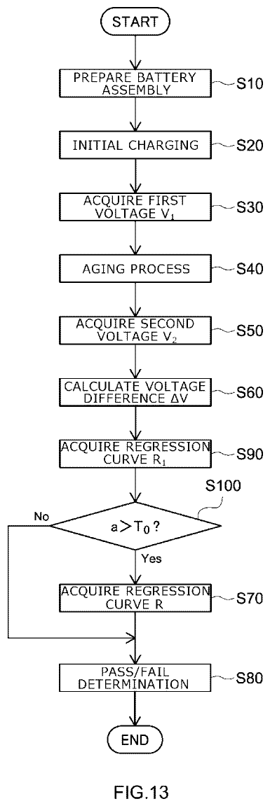

Further, the regression curve R may be a cubic regression curve R₃. FIG. 11 is an example of a graph for explaining acquisition of a regression curve R₃ represented by a cubic equation. The cubic regression curve R₃ can be represented by the following equation (6). When the voltage difference ΔV is corrected using the regression curve R₃, it is preferable to use the following equation (7). FIG. 12 is a graph obtained by correcting the graph illustrated in FIG. 11, using the regression curve R₃. Even when the correction using the cubic regression curve R₃ is performed, a corrected voltage difference ΔV_{z} from which variations due to the measurement start time have been eliminated can be obtained.

$$Y = {aX}^{3} + {bX}^{2} + cX + d \qquad ( 6 )$$

$${ΔV}_{z} = Y - ( {aX}^{3} + {bX}^{2} + cX + d ) \qquad ( 7 )$$

Although a description thereof is omitted, in the technology disclosed herein, a regression curve represented by a fourth- or higher-order polynomial may also be used. Even when a regression curve of fourth order or higher is used, a corrected voltage difference ΔV_{z} from which variations due to the measurement start time have been eliminated can be obtained. However, a higher-order regression curve tends to reflect, with high accuracy, a battery assembly 100 exhibiting an abnormal voltage difference ΔV (such as Sample A in FIG. 4). In such a case, a determination criterion (threshold) for defective products becomes easier to satisfy, and thus the detection accuracy for defective products may conversely decrease. From this viewpoint, the regression curve is preferably a cubic or lower-order curve (more preferably a linear straight line).

### Fourth Embodiment

In a fourth embodiment, before starting the regression curve acquisition step S70, a step of determining whether determination based on a regression curve is necessary is performed. FIG. 13 is a flowchart of a method for manufacturing a secondary battery according to the fourth embodiment. As illustrated in FIG. 13, in the manufacturing method according to the fourth embodiment, a regression straight line acquisition step S90 and a zero-th determination step S100 are provided between the voltage difference calculation step S60 and the regression curve acquisition step S70. Note that other steps may employ the same procedures as those in the manufacturing methods according to the first to third embodiments, and therefore, detailed descriptions thereof are omitted

### 1. Regression Straight Line Acquisition Step S90

In the regression straight line acquisition step S90, a regression straight line R₁ represented by a linear equation (Y=ax+b) is acquired. That is, in the present step, after the step of calculating the voltage difference ΔV is completed, the first voltage V₁ and the voltage difference ΔV of each of the plurality of battery assemblies 100 are plotted on coordinates having the first voltage V₁ as a first axis and the voltage difference ΔV as a second axis, thereby acquiring a regression straight line R₁ represented by the linear equation, which indicates a distribution tendency of the plurality of battery assemblies 100 on the coordinates. The procedure for acquiring the regression straight line R₁ is the same as that in the regression curve acquisition step S70 in the first embodiment, and a redundant description thereof is omitted.

### 2. Zero-Th Determination Step S100

In the zero-th determination step S100, a slope (a) of the regression straight line R₁ is compared with a predetermined zero-th threshold T₀, and when the slope (a) of the regression straight line R₁ is greater than the zero-th threshold T₀, the processing proceeds to the regression curve acquisition step S70. For example, when an aggregate in which variations in the voltage difference ΔV are small is obtained, the slope (a) of the regression straight line R₁ becomes small. Thus, defective products can be detected with high accuracy even without performing pass/fail determination based on the regression curve R. Thus, in the present step, when the slope (a) of the regression straight line R₁ is equal to or less than the zero-th threshold T₀ (No in S100), the regression curve acquisition step S70 is skipped and the pass/fail determination step S80 is performed. In this case, in the pass/fail determination step S80, it is determined whether an uncorrected voltage difference ΔV is equal to or greater than a threshold. Even in this case, defective products can be detected with high accuracy. On the other hand, when the slope (a) of the regression straight line R₁ is greater than the zero-th threshold T₀ (Yes in S100), the processing proceeds through the regression curve acquisition step S70, and the pass/fail determination step S80 based on the regression curve R is performed. Here, the regression curve acquisition step S70 in the present embodiment may use the linear regression straight line R₁ acquired in the regression straight line acquisition step S90 as it is, or alternatively may separately acquire a quadratic or higher-order regression curve R₂ or R₃ (see FIGS. 9 and 11) different from the regression straight line R₁.

### Fifth Embodiment

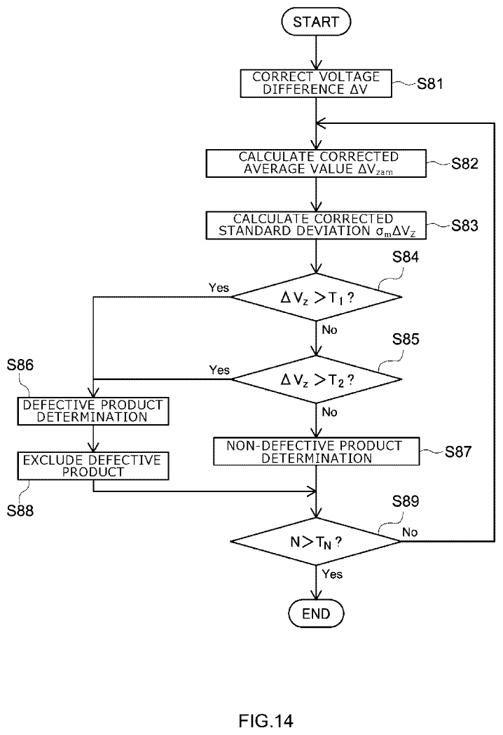

In all the embodiments described above, whether the battery assembly 100 is a defective product is determined based on a result of a single pass/fail determination process. However, in the manufacturing method disclosed herein, whether a battery assembly 100 is a defective product may be determined by repeatedly performing pass/fail determination a plurality of times. For example, FIG. 14 is a flowchart of a pass/fail determination step S80 in a fifth embodiment. As illustrated in FIG. 14, the manufacturing method according to the fifth embodiment differs from that of the first embodiment in that it includes a defective product exclusion step S88 and a cycle determination step S89.

### 1. Defective Product Exclusion Step S88

In the defective product exclusion step S88, a battery assembly 100 determined to be a defective product in step S86 is excluded from inspection targets. For example, in the example illustrated in FIG. 6, Sample A is determined to be a defective product. In this case, Sample A is deleted from original data of FIG. 6, and the processing proceeds to the cycle determination step S89.

### 2. Cycle Determination Step S89

In the cycle determination step S89, it is determined whether the number of times N the first determination step S84 has been performed exceeds a reference number T_{N}. The reference number T_{N} can be set to any number. From a viewpoint of both achieving the inspection accuracy and the manufacturing efficiency, the reference number T_{N} may be set within a range of 2 to 20 times (preferably 5 to 10 times). If the number of times N the first determination step S84 has been performed does not reach the reference number T_{N} (No in S84), the processing returns to the corrected average value calculation step S82. At this time, when data about the defective product has been deleted in the defective product exclusion step S88, a corrected average value ΔV_{zam} and a corrected standard deviation σmΔV_{z} are recalculated based on the aggregate from which the defective product exhibiting an abnormal corrected voltage difference ΔV_{z} has been excluded. Accordingly, the pass/fail determination can be performed with higher precision.

### Other Embodiments

The technology disclosed herein may encompass manufacturing methods other than the manufacturing methods according to the first to fifth embodiments described above. For example, in the above-described embodiments, steps for determining a battery assembly 100 having a small voltage difference ΔV before and after the aging step S40 as a defective product (the second determination step S85 and the fourth determination step S84a) are performed in order to detect defects caused by a measurement error derived from measurement equipment. However, the measurement errors derived from the measurement equipment occur less frequently than internal short circuits do and have a reduced adverse effect on battery performance, and therefore do not necessarily have to be eliminated. That is, the second determination step S85 and the fourth determination step S84a in the above-described embodiments are not essential matters in the manufacturing method disclosed herein.

The embodiments of the technology disclosed herein have been described above. Unless otherwise specified, the embodiments described in the present specification are not intended to limit the technology disclosed herein.

What is claim is:

1. A method for manufacturing a secondary battery, comprising the steps of:
measuring a first voltage V₁ for each of the plurality of battery assemblies, the first voltage V₁ being an inter-terminal voltage before an aging process;
performing the aging process for each of a plurality of battery assemblies;
measuring a second voltage V₂ for each of the plurality of battery assemblies, the second voltage V₂ being an inter-terminal voltage after the aging process;
calculating a voltage difference ΔV between the first voltage V₁ and the second voltage V₂ for each of the plurality of battery assemblies;
plotting the first voltage V₁ and the voltage difference ΔV in each of the plurality of battery assemblies on coordinates having the first voltage V₁ as a first axis and the voltage difference ΔV as a second axis, thereby acquiring a regression curve indicating a distribution tendency of the plurality of battery assemblies on the coordinates; and
performing pass/fail determination for each of the plurality of battery assemblies based on the regression curve.

2. The method for manufacturing a secondary battery according to claim 1, wherein the regression curve is a regression curve represented by a cubic or lower-order polynomial.

3. The method for manufacturing a secondary battery according to claim 2, wherein the regression curve is a regression straight line represented by a linear equation.

4. The method for manufacturing a secondary battery according to claim 3, wherein
the step of performing the pass/fail determination comprises the steps of:
correcting the voltage difference ΔV of each of the plurality of battery assemblies to a corrected voltage difference ΔV_{z} based on the following equation (1) when a slope of the regression straight line is denoted by (a) and an intercept thereof is denoted by (b);
calculating a corrected average value ΔV_{zam} that is an average value of the corrected voltage differences ΔV_{z} of the plurality of battery assemblies;
calculating a corrected standard deviation σₘΔV_{z} that is a standard deviation of the corrected voltage differences ΔV_{z} of the plurality of battery assemblies; and
setting a sum (ΔV_{zam}+σmΔV_{z}) of the corrected average value ΔV_{zam} and the corrected standard deviation σmΔV_{z} as a first threshold T₁, and determining a battery assembly having a corrected voltage difference ΔV_{z} exceeding the first threshold T₁ as a defective product.
$${ΔV}_{z} = ΔV - ( a \times {V}_{1} + b ) \qquad ( 1 )$$

5. The method for manufacturing a secondary battery according to claim 4, wherein
the step of performing the pass/fail determination further comprises the steps of:
setting a difference (ΔV_{zam}−σmΔV_{z}) between the corrected average value ΔV_{zam} and the corrected standard deviation σmΔV_{z} as a second threshold T₂, and determining a battery assembly having a corrected voltage difference ΔV_{z} less than the second threshold T₂ as a defective product.

6. The method for manufacturing a secondary battery according to claim 3, wherein
the step of performing the pass/fail determination comprises the steps of:
calculating an average value ΔVₐₘ of the voltage differences ΔV of the plurality of battery assemblies;
calculating a standard deviation σmΔV of the voltage differences ΔV of the plurality of battery assemblies; and
setting a value ΔV_{D1} represented by the following equation (2) as a third threshold T₃ when a slope of the regression straight line is denoted by (a), and determining a battery assembly having a voltage difference ΔV exceeding the third threshold T₃ as a defective product.
$${ΔV}_{D 1} = a \times {V}_{1} + ( {ΔV}_{am} + σ m ΔV ) \qquad ( 2 )$$

7. The method for manufacturing a secondary battery according to claim 6, wherein
the step of performing the pass/fail determination further comprises the step of:
setting a value ΔV_{D2} represented by the following equation (3) as a fourth threshold T₄ and determining a battery assembly having a voltage difference ΔV less than the fourth threshold T₄ as a defective product.
$${ΔV}_{D 2} = a \times {V}_{1} + ( {ΔV}_{am} - σ m ΔV ) \qquad ( 3 )$$

8. The method for manufacturing a secondary battery according to claim 1, further comprising the steps of:
after the step of calculating the voltage difference ΔV, plotting the first voltage V₁ and the voltage difference ΔV in each of the plurality of battery assemblies on coordinates having the first voltage V₁ as a first axis and the voltage difference ΔV as a second axis, thereby acquiring a regression straight line represented by a linear equation, the regression straight line indicating a distribution tendency of the plurality of battery assemblies on the coordinates; and
comparing a slope (a) of the regression straight line with a predetermined zero-th threshold T₀, and proceeding to a step of acquiring the regression curve when the slope (a) of the regression straight line is greater than the zero-th threshold T₀.
